(19) United States
(12) Patent Application Publication
(10) Pub. No.: US 2006/0131744 A1
(43) Pub. Date: Jun. 22, 2006

(54) Method and apparatus for providing a BGA connection having improved drop test performance

(76) Inventors: Shawn Martin O'Connor, McKinney, TX (US); Mark Allen Gerber, Plano, TX (US); Wyatt Allen Huddleston, Allen, TX (US)

Correspondence Address: TEXAS INSTRUMENTS INCORPORATED, P O BOX 655474, M/S 3999, DALLAS, TX, 75265, US

(21) Appl. No.: 11/017,444

(22) Filed: Dec. 20, 2004

(51) Int. Cl. H01L 21/44; H01L 23/52

(52) U.S. Cl. 257/737; 257/738; 438/613; 257/786; 438/612

(57) ABSTRACT

A BGA (Ball Grid Array Structure) having improved drop test performance by increasing the area of the solder bond at the corner of the array using existing assembling machinery.

### TECHNICAL FIELD

The present invention relates generally to integrated circuit chip package technology and more particularly to a BGA (Ball Grid Array) package having improved drop test performance.

### BACKGROUND

The ever increasing complexity of IC's and the demand for a smaller package size of these devices has resulted in the increased use of BOA bonded structures. However, as electronics find an ever increasing role in every aspect of modern life, these complex electronic circuits must withstand more severe environmental conditions including shock and G forces. Presently available laminate fine pitch BGA packages are proving to have a difficult time meeting the drop test requirements of many customers. Testing has shown that for large BGA structures the corner connections are the most likely to fail. One solution is to increase the size of the solder ball bond at the corner. Unfortunately present BGA assembly machinery cannot be used to place solder balls at the corner of the structure that are larger than the rest of the solder balls in the array.

Therefore, it would be advantageous if the existing assembly equipment solder ball structures could be used to form solder bonds having larger areas at the corner of the BGA structure than the areas of the solder bonds at the rest of the array.

### SUMMARY OF THE INVENTION

Accordingly, the present invention provides methods and structure comprising a BGA (Ball Grid Array) structure having improved drop test performance and that can be formed with existing assembly equipment. The ball grid array structure comprises an electronic device having a multiplicity of conductive terminal pads formed on a surface of the electronic device for bonding with solder balls such as for example a flip chip. According to one embodiment, the multiplicity of terminal pads are arranged in a plurality of equally spaced rows and columns so as to form a rectangular shaped array and such that each corner of the array is defined by three terminal pads including a corner terminal pad, a terminal pad in a row adjacent to the corner terminal pad, and a terminal pad in a column adjacent to the corner terminal pad. An anchor pad is included at least on one of the corners of the array and the anchor pad comprises the three terminal pads and a conductive layer extending between and in contact with the three terminal pads. A receiving or support surface also having a multiplicity of contact pads for bonding with solder balls is arranged in the plurality of equally spaced rows and column representing a mirror image array of the rectangular shaped array of terminal pads. The support surface also includes an anchor pad that is similar to, but a mirror image of the anchor pad on the electronic device. The anchor pad on the support surface also includes three contact pads defining a corner and a conductive layer extending between and in contact with the three contact pads. To join the two surfaces together, there is included a multiplicity of solder balls having a selected diameter, which electrically connects and bonds together one each terminal pad on the array of terminals on the electronic device to one each contact pad on the support surface. The constant diameter solder balls are selected so that each of the solder balls deform substantially uniformly when heated so that the surface of the electronic device is spaced parallel to and a constant distance from the support surface. According to the present invention there is also included an additional solder ball having the same selected diameter as the solder balls discussed above, and is bonded between the anchor pad on the electronic device and the anchor pad on the support surface. The additional solder ball is equally spaced between the three solder balls at a corner bonding the three terminal pads and the three contact pads of the structure together. The size of the contact pads or anchor pads is selected such that the additional solder ball and the three solder balls forming the corner flow together to form a corner solder bond having an increased size. The anchor pads may be of various selected sizes, and a preferred anchor pad comprises the three corner pads and another contact pad at a second row and a second column position from the current corner terminal pad.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 shows a prior art arrangement of an array of terminal or contact pads for receiving an array of solder balls for a BGA structure;

FIG. 2 illustrates four different corner arrangements for a BGA structure;

FIGS. 3A and 3B show a prior art arrangement of a partial BGA structure having equally spaced rows and columns of solder balls;

FIG. 4 shows the arrangement of FIG. 3A with the placement of an additional solder ball according to the teachings of the present invention;

FIG. 5 illustrates an anchor pad and solder ball arrangement according to one embodiment of the invention;

FIG. 5A is an enlarged side view of a corner arrangement of solder balls according to the present invention prior to solder flow, and FIGS. 5B, 5C, and 5D are various views of the embodiment of FIG. 5A after solder flow;

FIG. 6 is another embodiment of the invention similar to the embodiment of FIG. 5;

FIG. 7 illustrates the use of three solder balls in the normal array position and one additional solder ball in accordance with the teaching of the present invention, and the shape of the anchor pad;

FIGS. 7A, 7B, and 7C show enlarged views of the solder bonds of the embodiment of FIG. 7; and

FIG. 8 is another embodiment of the invention that is similar to, but the reverse of the embodiment of FIG. 7.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Presently available laminate fine pitch BGA packages comprising a chip package and a PCB or receiving surface have a difficult time meeting drop test requirements. Several approaches to solving the problem including different pad finishes such as CuOSP, bare copper, etc. have not been effective. Another approach that is effective but expensive and unacceptable to most customers is completing the bonding of the IC flip chip to the printed circuit board in the normal fashion and then under filling between the chip and the PCB with a molding compound to provide additional support. Still another approach that does provide significant improvement in the drop test results without the requirement of under filling is to maximize the amount of solder area between the BGA chip package and the PCB (Printed Circuit Board) to which the chip package is mounted.

However, increasing the solder area between all of the multiplicity (sometimes several hundred) of anchor pad connections by using solder balls with a larger diameter would significantly and unacceptably increase the overall size of the finished package. Furthermore, tests have indicated that the area of greatest stress and consequently the area of greatest failure is overwhelmingly at the corners of the package. Therefore, increasing the solder area of all of the hundreds of solder ball connections would also be overkill. The simple answer therefore would appear to be, simply increase the size of the solder balls at the corner of the package or other areas known to have excessive stress. Unfortunately, presently available manufacturing assembly equipment does not permit the use of different size or shapes of solder balls in the same BGA package. More specifically, because of how the solder ball placement and/or assembly machinery operates, the use of different size solder balls would require a different machine step for each different size of solder ball or a complete redesign of the equipment. As will be appreciated by those skilled in the art, a vacuum placement plate having an array of holes that is the same pattern as the anchor pads on the chip package and on the receiving surface or PCB is placed in a container of thousands of solder balls each having the same diameter. The array of holes in the vacuum placement plate, however, has a diameter that is smaller than the diameter of the solder balls so that one solder ball is held in place at each hole in the placement plate array. Therefore, once there is a solder ball in place at every hole, the solder balls are placed and aligned on the anchor pads of the chip package. The solder balls and the anchor pads on the chip are then sufficiently heated in a manner well known by those skilled in the art to bond the solder balls with the anchor pads to substantially complete the package. The chip package with the bonded solder balls is then shipped to the customer and/or user where it is typically bonded to a receiving surface such as a PCB (Printed Circuit Board). Therefore, it is seen that the present BGA assembly machinery simply does not lend itself to the use of different size solder balls to achieve a larger solder area in a few selected spots such as for example the four corners of the structure. Furthermore, even if larger solder balls could be automatically placed at specific areas where an increased solder area was desired, there would still be a major problem. Namely, coplanararity between the IC chip and the PCB. More specifically, an important reason for all solder balls to have a carefully controlled constant diameter is to assure coplanararity. The coplanararity helps to assure reliable electrical connections between each opposing pair of anchor pads through the solder ball after heating or solder flow.

The present invention provides an increased solder area at selective locations on the structure in a manner that uses constant diameter solder balls and thus is compatible with existing assembly equipment or machinery.

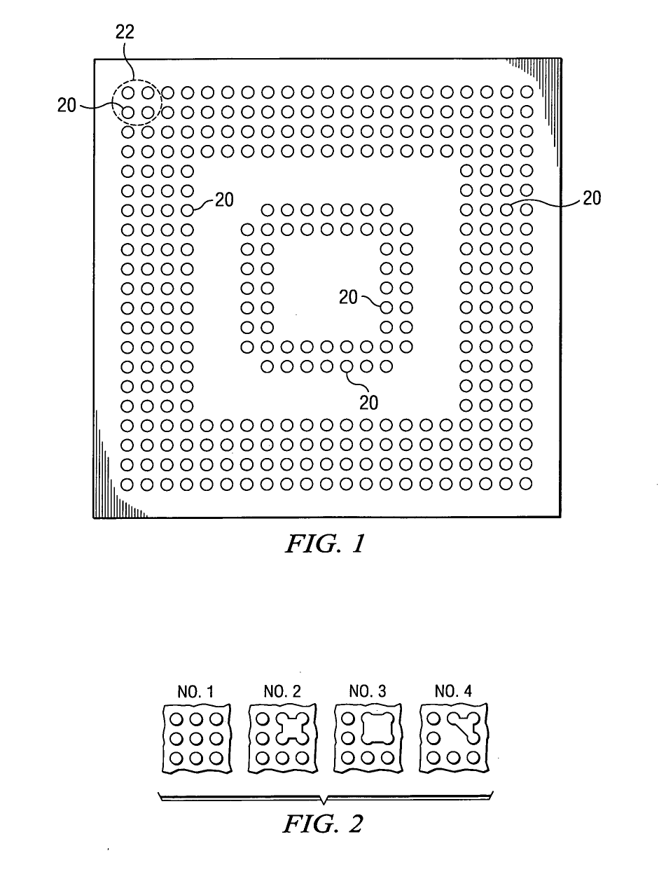

Referring now to FIG. 1 there is shown an array of anchor pads 20 on, for example only, an IC chip that will receive a multiplicity (333) of solder balls for a BGA (Ball Grid Array) suitable for bonding with a similar (a mirror image) array of anchor pads on a receiving surface or PCB. As mentioned above, the areas of most failures that occur in drop testing are the four corners such as the upper left hand corner as indicated by reference number 22 of the figure.

However, as was also mentioned above, increasing the solder area is one solution to the problem and testing various configurations of corner solder areas has determined the bonding strength for difficult shaped areas of the solder bond. FIG. 2 illustrates examples of four different corner arrangements that were evaluated and are not intended to be exclusive. The first or No. 1 arrangement is the “control” arrangement and represents no increase in the solder area and as would be suspected, shows the lowest performance during drop a test. The remaining arrangements, No. 2, No. 3, and No. 4, were also evaluated by drop tests, and unsurprisingly showed that the No. 3 arrangement had the highest reliability followed with the No. 2 arrangement and then the No. 4 arrangement.

However, as discussed above, the real problem is how to achieve such increased solder areas such as shown in the No. 2, No. 3, and No. 4 arrangements with the existing automatic equipment or machinery so that such bonded BGA structures can be automatically manufactured or mass assembled in large quantities.

Further, as will be appreciated by those skilled in the art. Increasing the size of the corner anchor pad, which, as is discussed below, is comprised of the three corner terminal pads and the conductive layer extending between the three terminal pads. This increased size may be readily accomplished by masking and etching the conductive layer on the flip chip or PCB or receiving surface. However, automatically placing a solder ball having a larger diameter or different shape than the rest of the solder balls in the array with existing automatic equipment is not only difficult but causes other problems.

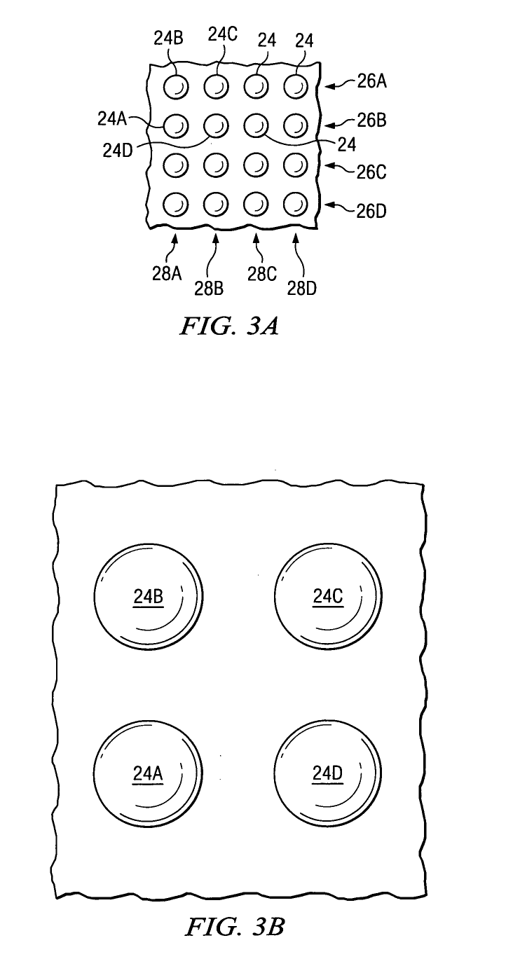

Referring now to FIGS. 3A and 3B there is shown a typical prior art arrangement or array of anchor pads and/or solder balls 24. FIG. 3A illustrates the upper left hand area of a rectangular or square shaped array. As is also seen in FIG. 3A, the anchor pads/solder balls are arranged in equally spaced rows 26a, 26b, 26c, and 26d and equally spaced columns 28a, 28b, 28c, and 28d. FIG. 3B shows an example of a typical arrangement of four solder balls from the array of FIG. 3A.

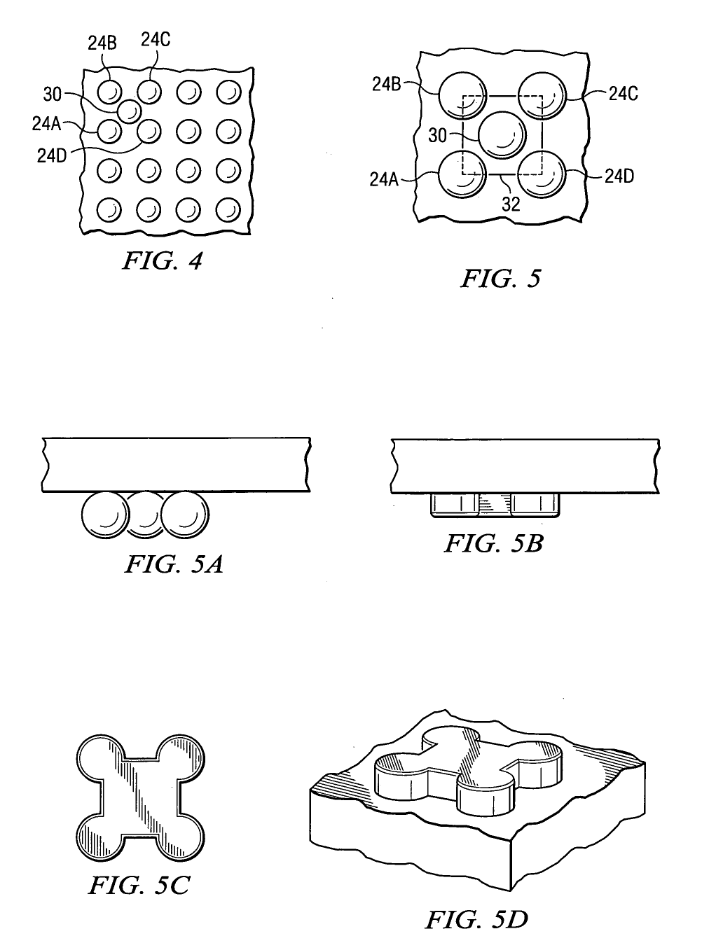

FIG. 4 illustrates the placement of an additional solder ball 30 between the four corner solder balls 24a, 24b, 24c, and 24d. Solder ball 30 has the same constant diameter and equally spaced from the four corner solder balls 24a, 24b, 24c, and 24d according to the present invention. The placement of the additional solder ball 30 may be accomplished with existing machinery and equipment and only requires a slight modification of the vacuum placement table by simply adding another hole equally spaced between the corner holes for the corner solder balls. However, this is not a major concern since a new and different vacuum placement table is typically required for each different chip. This is because the size, number, and location of anchor pads on a chip are not always the same. Therefore, the shape of the anchor pad is designed to have a larger surface area. Thus, when the structure with the solder balls 24a, 24b, 24c, and/or 24d and the additional solder ball 30 is heated, the solder balls soften so as to flow together and form a single solder bond between the anchor pads on the IC chip and the anchor pads on the receiving surface or PCB having the increased area while still maintaining the IC chip and the PCB parallel to and equally spaced from each other.

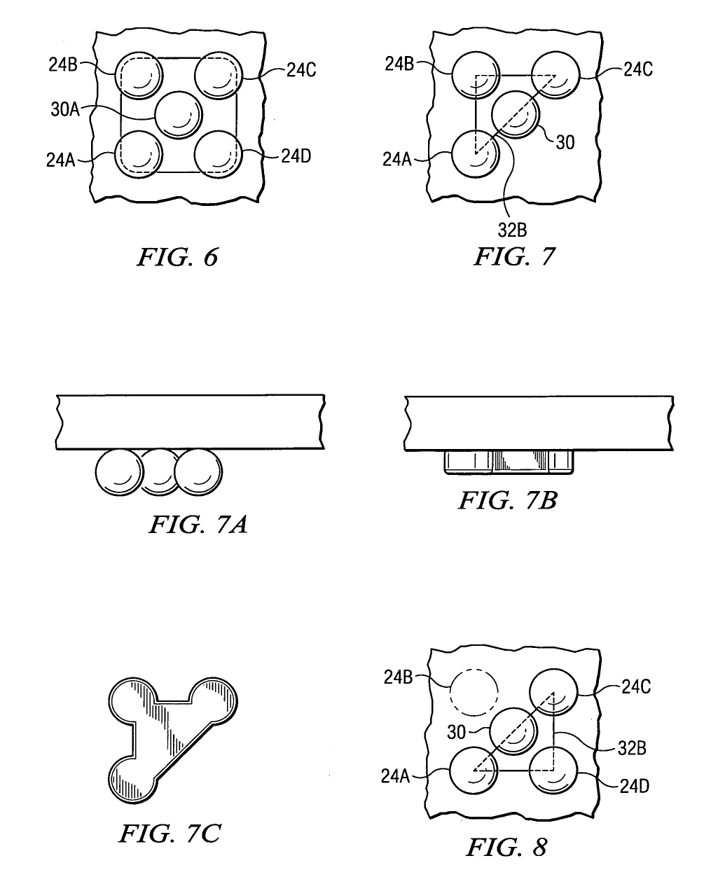

FIG. 5 is similar to FIG. 3B except that it includes the additional solder ball 30, and also shows the outline of the anchor pad 32 for producing the No. 2 corner example of FIG. 2 discussed above. FIG. 5A is a side view of the solder balls in place on a chip prior to being placed in contact with the PCB or receiving surfaces (not shown) and prior to re-flow. FIG. 5B is side view of the increased solder area after re-flow. FIG. 5C is top view of the increased solder area and FIG. 5D is perspective view of the increased solder area. FIG. 6 is a variation of FIG. 5 except the anchor pad area 32a is larger so that the footprint or shape of the anchor pad 32a is almost square shaped and has less of a shamrock shape.

FIG. 7 illustrates the use of three solder balls 24a, 24b, and 24c to form the solder bond of the example number 4 of FIG. 2, and FIG. 7 also illustrates the shape of the anchor pad 32b that is formed on the IC chip and the receiving surface. Likewise, FIGS. 7A, 7B, and 7C, show the enlarged views of the solder bond in the same manner as discussed above with respect to FIG. 5.

FIG. 8 illustrates still another embodiment of the invention. The solder ball layout of FIG. 8 is similar to, but substantially the reverse of the layout of FIG. 7 in that the corner solder ball 24b (shown in dotted lines) is eliminated and the additional solder ball 30 is placed between the two outmost remaining solder balls 24a and 24c. Thus, the anchor pad 32b and the resulting solder bond forms a truncated corner with reduced stress concentrators.

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, manufacture, means, methods and steps described in the specification. As one of ordinary skill in the art will readily appreciate from the disclosure of the present invention, processes, manufacture, means, methods, or steps, presently existing or later to be developed, that perform substantially the same function or achieve substantially the same result as the corresponding embodiments described herein may be utilized according to the present invention. Accordingly, the appended claims are intended to include within their scope such processes, manufacture, means, methods, or steps.

1. A ball grid array (BGA) structure having improved drop test performance comprising:
an electronic device having a multiplicity of conductive terminal pads formed on a surface of said electronic device for bonding with solder balls, said multiplicity of terminal pads arranged in a plurality of equally spaced rows and columns so as to form a rectangular shaped array and such that each corner of said array is defined by at least three terminal pads;
an anchor pad on at least one corner of said array, said anchor pad comprising said at least three terminal pads and a conductive layer extending between and in contact with said three terminal pads;
a support surface having a multiplicity of contact pads for bonding with solder balls, said multiplicity of contact pads arranged in a plurality of equally spaced rows and columns representing a mirror image array of said rectangular shaped array of terminal pads;
an anchor pad on said support surface corresponding to said anchor pad on said electronic device, said support surface anchor pad comprising three contact pads and a conductive layer extending between and in contact with said three contact pads;
a multiplicity of solder balls having a selected diameter electrically connecting and bonding together one each terminal pad on said array of terminals on said electronic device to one each contact pad on said support surface, each of said solder balls deforming substantially uniformly such that said surface of said electronic device is spaced parallel to and at a constant distance from said support surface; and
an additional solder ball having said selected diameter bonded between said anchor pad on said electronic device and said anchor pad on said support surface, said additional solder ball equally spaced between the three solder balls bonding said three terminal pads and said three contact pads together at said at least one corner and wherein said additional solder ball and said three solder balls flow together to form a corner solder bond having increased size.

2. The BGA structure of claim 1 wherein said at least three terminal pads defining a corner include a corner terminal pad, a terminal pad in a row adjacent said corner terminal pad, and a terminal pad in a column adjacent said corner terminal pad and wherein said anchor pad on said electronic device and said anchor pad on said support surface comprise another terminal pad and another contact pad respectively, and said bond comprises another solder ball located between the terminal pad and the corresponding contact pad at a second row and a second column position from the corner terminal pad.

3. The BGA structure of claim 1 comprising an anchor pad on at least two corners and wherein said additional solder ball comprises at least two additional solder balls.

4. The BGA structure of claim 1 comprising an anchor pad on each corner and wherein said additional solder ball comprises four additional solder balls.

5. The BGA structure of claim 1 wherein the surface area of said conductive layer extending between said three terminal pads is selected to distribute the solder of said additional solder balls so as to maintain said constant distance between said surface of said electronic device and said support surface.

6. The BOA structure of claim 2 wherein the surface of said conductive layer of said anchor pad is selected to maintain said constant distance between said surface of said electronic device and said support surface.

7-12. (canceled)

13. A ball grid array (BOA) structure having improved drop test performance comprising:
an electronic device having a multiplicity of conductive terminal pads formed on a surface of said electronic device for bonding with solder balls, said multiplicity of terminal pads arranged in an array such that a corner of said array is defined by at least three terminal pads;
an anchor pad on at least one corner of said array, said anchor pad comprising said three terminal pads and a conductive layer extending between and in contact with said three terminal pads;
a support surface having a multiplicity of contact pads for bonding with solder balls, said multiplicity of contact pads arranged in a mirror image array of said array of terminal pads;
an anchor pad on said support surface corresponding to said anchor pad on said electronic device, said support surface anchor pad comprising three contact pads and a conductive layer extending between and in contact with said three contact pads;
a multiplicity of solder balls electrically connecting and bonding together terminal pads on said electronic device to contact pads on said support surface; and
an additional solder ball bonded between said anchor pad on said electronic device and said anchor pad on said support surface, said additional solder ball equally spaced between the three solder balls bonding said three terminal pads and said three contact pads together at said at least one corner and wherein said additional solder ball and said three solder balls flow together to form a corner solder bond having increased size.

14. The BGA structure of claim 13 wherein said at least three terminal pads include a corner terminal pad, a terminal pad in a row adjacent said corner terminal pad, and a terminal pad in a column adjacent said corner terminal pad and wherein said anchor pad on said electronic device and said anchor pad on said support surface comprise another terminal pad and another contact pad respectively, and said bond comprises another solder ball located between the terminal pad and the corresponding contact pad at a second row and a second column position from the corner terminal pad.

15. The BGA structure of claim 13 comprising an anchor pad on at least two corners and wherein said additional solder ball comprises at least two additional solder balls.

16. The BGA structure of claim 13 comprising an anchor pad on each corner and wherein said additional solder ball comprises four additional solder balls.

17. The BGA structure of claim 13 wherein the surface area of said conductive layer extending between said three terminal pads is selected to distribute the solder of said additional solder balls so as to maintain a constant distance between said surface of said electronic device and said support surface.

18. The BGA structure of claim 14 wherein the surface of said conductive layer of said anchor pad is selected to maintain said constant distance between said surface of said electronic device and said support surface.
